(19) United States
(12) Patent Application Publication
(10) Pub. No.: US 2021/0073317 A1
(43) Pub. Date: Mar. 11, 2021

(54) PERFORMING DOT PRODUCT OPERATIONS USING A MEMRISTIVE CROSSBAR ARRAY

(71) Applicant: INTERNATIONAL BUSINESS MACHINES CORPORATION, ARMONK, NY (US)

(72) Inventors: Martino Dazzi, Thalwil (CH); Pier Andrea Francese, ADLISWIL (CH); Abu Sebastian, Adliswil (CH); Manuel Le Gallo-Bourdeau, Zurich (CH); Evangelos Stavros Eleftheriou, Rueschlikon (CH)

(21) Appl. No.: 16/561,110

(22) Filed: Sep. 5, 2019

(51) Int. Cl. G06F 17/15; G11C 13/00; G06N 3/02

(52) U.S. Cl. CPC G06F 17/153; G06F 7/00; G06N 3/02; G11C 13/0002

(57) ABSTRACT

A method, computer system, and computer program product of performing a matrix convolution on a multidimensional input matrix for obtaining a multidimensional output matrix. The matrix convolution may include a set of dot product operations for obtaining all elements of the output matrix. Each dot product operation of the set of dot product operations may include an input submatrix of the input matrix and at least one convolution matrix. The method may include providing a memristive crossbar array configured to perform a vector matrix multiplication. A subset of the set of dot product operations may be computed by storing the convolution matrices of the subset of dot product operations in the crossbar array and inputting to the crossbar array one input vector comprising all distinct elements of the input submatrices of the subset.

### BACKGROUND

The present invention relates to the field of digital computer systems, and more specifically, to a method for performing a set of a matrix convolution on a multidimensional input matrix for obtaining a multidimensional output matrix using a memristive crossbar array.

The computational memory is a promising approach in the field of non-von Neumann computing paradigms, in which nanoscale resistive memory devices are simultaneously storing data performing basic computational tasks. For example, by arranging these devices in a crossbar configuration, matrix-vector multiplications may be performed. However, there is a continuous need to improve the usage of these crossbar configurations.

### BRIEF SUMMARY

Various embodiments of the present invention provide a method for performing a matrix convolution on a multidimensional input matrix for obtaining a multidimensional output matrix using a memristive crossbar array, and crossbar array as described by the subject matter of the independent claims. Embodiments of the present invention can be freely combined with each other if they are not mutually exclusive.

In one embodiment, the invention relates to a method for performing a matrix convolution on a multidimensional input matrix for obtaining a multidimensional output matrix. The matrix convolution may involve a set of dot product operations for obtaining all elements of the output matrix. Each dot product operation of the set of dot product operations may involve an input submatrix of the input matrix and at least one convolution matrix. The method may include providing a memristive crossbar array configured to perform a vector matrix multiplication, computing a subset of the set of dot product operations by storing the convolution matrices of the subset of dot product operations in the crossbar array, and inputting to the crossbar array one input vector comprising all distinct elements of the input submatrices of the subset.

In another embodiment, the invention relates to a memristive crossbar array for performing a matrix convolution on a multidimensional input matrix for obtaining a multidimensional output matrix. The matrix convolution may involve a set of dot product operations for obtaining all elements of the output matrix. Each dot product operation of the set of dot product operations may involve an input submatrix of the input matrix and at least one convolution matrix. The crossbar array may be configured to store the convolution matrices in the crossbar array such that one input vector comprising all distinct elements of the input submatrices can be input to the crossbar array in order to perform a subset of dot product operations of the set of dot product operations.

### BRIEF DESCRIPTION OF THE DRAWINGS

In the following embodiments of the invention are explained in greater detail, by way of example only, making reference to the drawings in which:

FIG. 1 depicts a crossbar array of memristors;

FIG. 2 is a flowchart of a method for performing multiple dot product operations in accordance with an embodiment of the present invention;

FIG. 3 is a block diagram illustrating a method for multiple dot product operations in accordance with an embodiment of the present invention;

FIG. 4 is a flowchart of a method for performing at least part of an inference process of a convolutional neural network in accordance with an embodiment of the present invention;

FIG. 5A is a block diagram illustrating a method for multiple dot product operations in accordance with an embodiment of the present invention;

FIG. 5B is a block diagram illustrating a method for multiple dot product operations in accordance with an embodiment of the present invention;

FIG. 6 is a block diagram illustrating a method for multiple dot product operations in accordance with an embodiment of the present invention;

FIG. 7 illustrates a graph representation of one ResNet architecture in accordance with an embodiment of the present invention;

FIG. 8 is a block diagram of a system in accordance with an embodiment of the present invention;

FIG. 9 illustrates a cloud computing environment, in accordance with an embodiment of the invention; and

FIG. 10 illustrates a set of functional abstraction layers provided by the cloud computing environment of FIG. 9, in accordance with an embodiment of the invention.

### DETAILED DESCRIPTION

The descriptions of the various embodiments of the present invention will be presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The matrix-vector multiplication of a matrix W and vector x may be realized through the memristive crossbar array by representing each matrix element with the conductance of the corresponding memristor element of the array. The multiplication of the matrix W and vector x may be performed by inputting voltages representing the vector values to the crossbar array. The resulting currents are indicative of the product of W and x. A resistive memory element (or device) of the crossbar array may for example be one of a phase change memory (PCM), metal-oxide resistive RAM, conductive bridge RAM and magnetic RAM. In another example, the crossbar array may comprise charge-based memory elements such as SRAM and Flash (NOR and NAND) elements. A representation scheme of the matrix W and conductance G of the crossbar array that enables to obtain the final product may be the following scheme

$${W}_{ij} = \frac{{W}_{max}}{{G}_{max}} {G}_{ij} \qquad Equation X$$

where Gₘₐₓ is given by the conductance range of the crossbar array and Wₘₐₓ is chosen depending on the magnitude of matrix W.

Embodiments of the present invention may provide an area efficient usage of a crossbar array. This may enable an improved parallel computation of dot product operations. By providing a single vector that has all the elements of the input submatrices, the convolution matrices may be stored in a compact way in the crossbar array. For example, embodiments of the present invention may be used for learning and inferring neural networks.

A submatrix of the multidimensional input matrix may also be a multidimensional matrix. For example, the size of the input matrix may be defined as xᵢₙ*yᵢₙ*dᵢₙ and the size of the submatrix of the input matrix may be defined as

subxᵢₙ*subyᵢₙ*dᵢₙ Equation X

where subxᵢₙ<xᵢₙ and subyᵢₙ<yᵢₙ and dᵢₙ is the same for the input matrix and its submatrix. The columns of a submatrix of the input matrix are consecutive columns of the input matrix and the rows of the submatrix are consecutive rows of the input matrix. The multidimensional input matrix may be referred to as feature map having dᵢₙ channels. The submatrix may comprise dᵢₙ channel-matrices of size subxᵢₙ*subyᵢₙ. The channel-matrices of the submatrix have the same element positions (subxᵢₙ, subyᵢₙ). A dot product operation of the set of dot product operations involves an input submatrix of the input matrix and at least one distinct convolution matrix. For example, the dot product operation of submatrix subxᵢₙ*subyᵢₙ*dᵢₙ involves dᵢₙ kernels, wherein each kernel has the size subxᵢₙ*subyᵢₙ. The dᵢₙ kernels may be the same or different kernels.

The multidimensional output matrix may have a size of xₒᵤₜ*yₒᵤₜ*dₒᵤₜ. An element of the output matrix may be defined by a single value or element (xₒᵤₜ, yₒᵤₜ, dₒᵤₜ). A pixel of the output matrix may be defined by clout elements. An element of the output matrix may be obtained by a dot product of a submatrix subxᵢₙ*subyᵢₙ*dᵢₙ and dᵢₙ kernels, wherein the dᵢₙ kernels are associated with the channel of the output matrix to which said element belongs. That is, for obtaining all elements of the output matrix, dₒᵤₜ*dᵢₙ kernels of size (subxᵢₙ, subyᵢₙ) may be used for performing the set of dot product operations.

According to one embodiment, the computing step comprises selecting the subset of dot product operations such that the computation of the subset of dot product operations result in elements along two dimensions of the output matrix and such that each selected subset of dot product operations involves a different input vector. The subset of dot product operations is selected so that they can be performed at once by the crossbar array. For example, by inputting all elements of the input vector at the same time to the crossbar array, the subset of dot product operations may be performed in parallel.

According to one embodiment, the computing step may include selecting the subset of dot product operations such that the computation of the subset of dot product operations result in elements along three dimensions of the output matrix and such that each selected subset of dot product operations involves a different input vector.

According to one embodiment, a training or inference of a convolutional neural network (CNN) involves, at each layer of the CNN, a layer operation that can be computed by a memristive crossbar array, wherein the matrix convolution is the layer operation of a given layer of the CNN.

According to one embodiment, the method may include providing further memristive crossbar arrays such that each further layer of the CNN is associated with a memristive crossbar array, interconnecting the memristive crossbar arrays for execution in a pipelined fashion, and performing the computation step for each further layer of the CNN using a respective subset of dot product operations and the memristive crossbar array associated with the further layer.

According to one embodiment, the subset of dot product operations computed by each memristive crossbar array may be selected such that the bandwidth requirement for each interconnection between the interconnected memristive crossbar arrays is identical.

According to one embodiment, the memristive crossbar array may include row lines and column lines intersecting the row lines. The resistive memory elements may be coupled between the row lines and the column lines at the junctions formed by the row and column lines. Each resistive memory element of the resistive memory elements may represent an element of a matrix, wherein storing the convolution matrices comprises for each dot product operation of the subset of dot product operations storing all elements of convolution matrices involved in the dot product operation in resistive memory elements of a respective single column line of the crossbar array. This may enable a compact storage of the convolution matrices and may enable to use the crossbar array for further parallel computations.

According to one embodiment, the columns lines of the convolution matrices may be consecutive lines of the crossbar array. This may enable a compact storage of the convolution matrices and may enable to use the crossbar array for further parallel computations.

According to one embodiment, the memristive crossbar array comprises row lines and column lines intersecting the row lines, and resistive memory elements coupled between the row lines and the column lines at the junctions formed by the row and column lines. A resistive memory element of the resistive memory elements may represent an element of a matrix, wherein storing of the convolution matrices may include storing all elements of convolution matrices involved in each dot product operation of the subset of dot product operations in a respective column line. The column lines of the convolution matrices may be consecutive lines of the crossbar array.

According to one embodiment, the memristive crossbar array comprises row lines and column lines intersecting the row lines, and resistive memory elements coupled between the row lines and the column lines at the junctions formed by the row and column lines. A resistive memory element of the resistive memory elements may represent an element of a matrix, wherein storing of the convolution matrices may include identifying a group of convolution matrices that are to be multiplied by the same input submatrix, storing all elements of each convolution matrix of the group in a same column line, and repeating the identifying step and storing step for zero or more further groups of convolution matrices of the subset of dot product operations. This embodiment may make efficient use of the surface of the crossbar array. This may enable to perform a maximum number of parallel dot product operations.

According to one embodiment, the memristive crossbar array comprises row lines and column lines intersecting the row lines, and resistive memory elements coupled between the row lines and the column lines at the junctions formed by the row and column lines, a resistive memory element of the resistive memory elements representing an element of a matrix. This may enable a controlled production of the crossbar arrays that is well suitable for performing dot product operations.

According to one embodiment, the method further comprises training a convolutional neural network (CNN). The CNN may be configured to perform the inputting and the storing steps.

According to one embodiment, the CNN may be configured to perform further sets of dot product operations using the crossbar array by performing the storing of all convolution matrices and repeating the inputting steps for each set of the further sets. The set of dot product operations and the further sets of dot product operations may form all dot product operations required during the inference of the CNN.

According to one embodiment, the CNN may be configured to perform further sets of dot product operations using the crossbar array by consecutively repeating the storing and the inputting steps for each set of the further sets.

Embodiments of the present invention may be advantageous as they may enable to compute the most expensive computations involved in the training or inference of a CNN. For example, the inference stage of a CNN may be dominated in complexity by convolutions. For example, convolutional layers of the CNN contain more than 90% of the total required computations. For example, the training of the CNN or the inference of a trained CNN may involve operations or computations such as dot products or convolutions at each layer of the CNN. A dot product operation can be computed through many multiply-accumulate operations, each of which computes the product of two operands and adds the result. In CNNs, the number of total dot product operations is relatively high, for example, for a 224×224 image, a single category labeling classification with 1000 classes requires close to 1 Giga operations using AlexNet.

Embodiments of the present invention may make use of parallel feature map activation computation to provide a pipeline speedup for the execution of CNNs while keeping the same communication bandwidth and memory requirement. In a pipelined execution of a CNN, at every computational cycle one feature pixel across all channels may be computed. Feature map pixels are communicated to a next in-memory computational unit in the pipeline.

According to one embodiment, the input matrices are activation matrices of feature maps of a CNN and the convolution matrices are kernels.

According to one embodiment, the input matrices are pixels of an image or activation matrices of feature maps of a CNN.

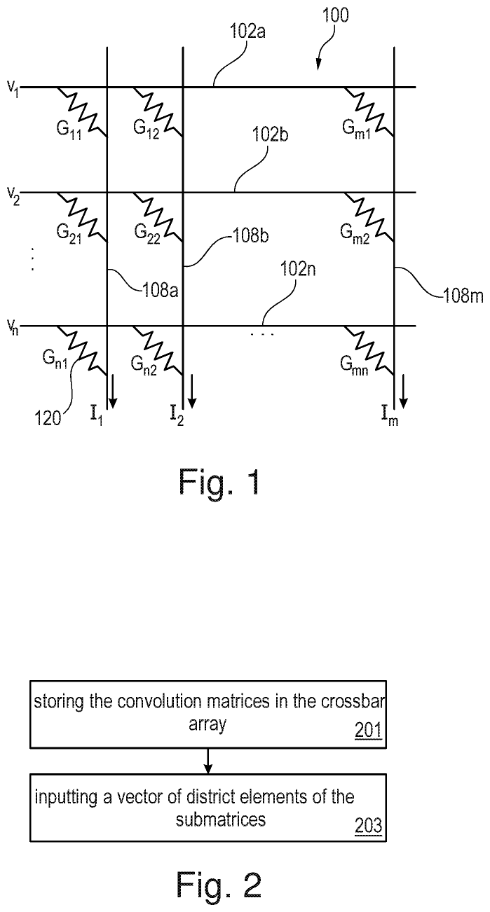

FIG. 1 depicts a crossbar array of memristors (or resistive processing units (RPUs)) that provide local data storage along with voltage sequences illustrating the operation of the memristors. FIG. 1 is a diagram of a two-dimensional (2D) crossbar array 100 that may for example perform a matrix-vector multiplication. Crossbar array 100 is formed from a set of conductive row wires 102a . . . 102n and a set of conductive column wires 108a . . . m that intersect the set of conductive row wires 102a-n.

The conductive column wires may be referred to as column lines and conductive row wires may be referred to as row lines. The intersections between the set of row wires and the set of column wires are separated by memristors, which are shown in FIG. 1 as resistive elements each having its own adjustable/updateable resistive weight or conductance, depicted as Gᵢⱼ, respectively where i=1 . . . n, and j=1 . . . m. For ease of illustration, only one memristor 120 is labeled with a reference number in FIG. 1. FIG. 1 provides an example with memristors for exemplification purpose and it is not limited to. For example, the intersections between the set of row wires and the set of columns of the crossbar array may comprise charge-based memory elements instead of memristors.

Input voltages v₁ . . . vₙ are applied to row wires 102a-n respectively. Each column wire 108a-n sums the currents I₁, I₂ . . . Iₘ generated by each memristor along the particular column wire. For example, as shown in FIG. 1, the current I₂ generated by column wire 108_{b} can be represented as Equation 1, as follows:

I₂=v₁·G₂₁+v₂·G₂₂+v₃·G₂₃+ . . . +vₙ·G₂ₙ. Equation 1

Thus, array 100 computes the matrix-vector multiplication by multiplying the values stored in the memristors by the row wire inputs, which are defined by voltages v₁₋ₙ. Accordingly, the multiplication may be performed locally at each memristor 120 of array 100 using the memristor itself plus the relevant row or column wire of array 100.

The crossbar array of FIG. 1 may for example enable to compute the multiplication of a vector x with a matrix W. The items Wᵢⱼ of the matrix W may be mapped onto corresponding conductances of the crossbar array in accordance with Equation 2, as follows:

$${W}_{ij} = \frac{{W}_{max}}{{G}_{max}} {G}_{ij} , \qquad Equation 2$$

where Gₘₐₓ is given by the conductance range of the crossbar array 100 and Wₘₐₓ is chosen depending on the magnitude of matrix W.

The size of the crossbar array 100 may be determined by the number of row lines n and the number of column lines m, wherein the number of memristors is n×m. In one example, n=m.

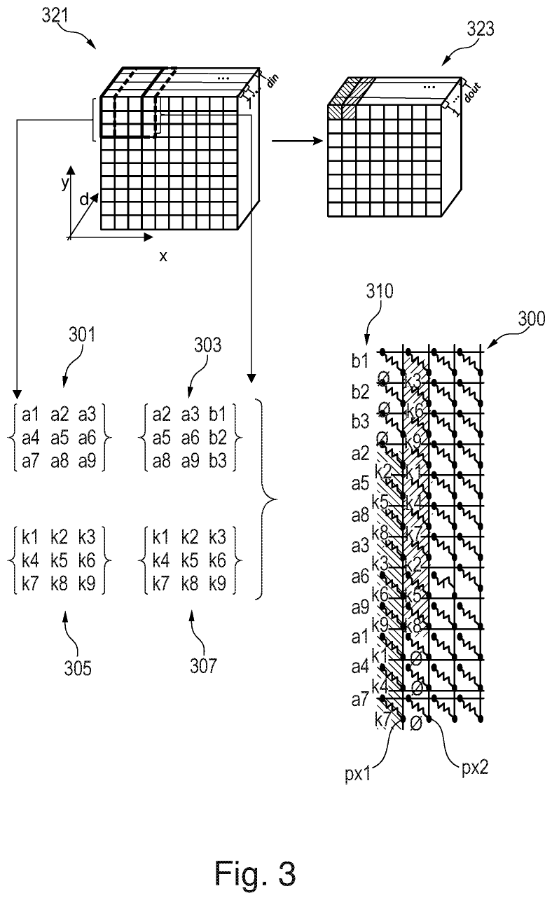

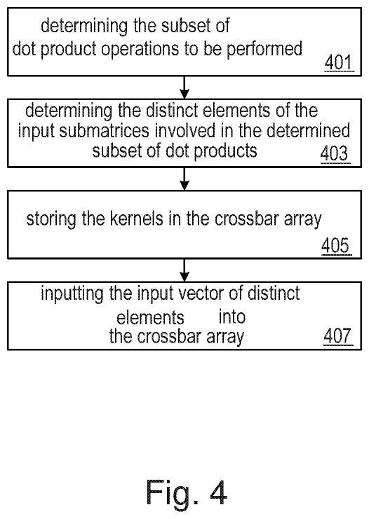

FIG. 2 is a flowchart of a method for performing at least part of a matrix convolution on a multidimensional input matrix. The matrix convolution may result in a multidimensional output matrix. For simplification purpose, the method of FIG. 2 is described with reference to the example of FIG. 3, but it is not limited to. For example, the input matrix 321 is shown in FIG. 3 as having dimensions xᵢₙ, yᵢₙ and dᵢₙ defining a number of xᵢₙ*yᵢₙ*din elements. FIG. 3 further shows the output matrix 323 as having xᵢₙ, yᵢₙ, dout defining a number of xₒᵤₜ*yₒᵤₜ*dout elements. For simplification of the description, din and dout are chosen to equal to 1 in the example of FIG. 3.

In order to obtain all elements of the output matrix 323, the matrix convolution on the input matrix 321 may involve a set of dot product operations. For example, the set of dot product operations may involve din*dout convolution matrices of size k*k. For example, one element of the output matrix 323 may be obtained by a respective dot product operation, wherein the result of the dot product operation may be the output of a single column of the crossbar array. That single column may store all convolution matrices needed to perform that dot product operation. The set of dot product operations may be split into multiple subsets of dot product operations such that each subset of dot product operations may be performed in parallel by a crossbar array e.g. 100. If for example, a single crossbar array is used, all the elements of the output matrix may be obtained by processing (e.g. consecutively) each of the subsets of dot product operations in the crossbar array. For example, for performing two subsets of dot product operations, all convolution matrices of said subsets are stored in the crossbar array and the two input vectors of said subsets are consecutively input to the crossbar array.

Each dot product operation of the set of dot product operations involves an input submatrix of the input matrix 321 and at least one distinct convolution matrix. Each dot product yields one element of the output matrix 323. The input submatrices have a size of

(subxᵢₙ*subyᵢₙ)*1 Equation X

where subxᵢₙ<xᵢₙ and subyᵢₙ<yᵢₙ. The dot product operation is the process of multiplying locally similar entries of two matrices and summing the sum results. Each dot product operation of the set of dot product operations may involve an input submatrix having the same size as the size of the convolution matrix. The input submatrices for different dot products may share elements. The terms “input submatrix” and “convolution matrix” are used for naming purpose to distinguish the first (left operand) and second (right operand) operands of a dot product operation.

FIG. 3 shows two input submatrices 301 and 303 and two corresponding convolution matrices 303 and 307. As indicated in FIG. 3, the two input submatrices 301 and 303 may be part of the input matrix 321 having a depth din=1 and may be used to obtain elements of the output matrix 323 which has a depth dout=1. Each of the two input submatrices 301 and 303 may have a size of

subxᵢₙ*subyᵢₙ*1 Equation X

where subxᵢₙ<xᵢₙ and subyᵢₙ<yᵢₙ. The example of FIG. 3 describes two dot product operations. In this example of FIG. 3, the first dot product operation involves the input submatrix 301 and the convolution matrix 305. The second dot product operation involves the input submatrix 303 and the convolution matrix 307. For exemplification purpose, the convolution matrices 305 and 307 are the same, but they may be different. The input submatrices 301 and 303 share the elements a2, a3, a5, a6, a8 and a9. This is also illustrated on input matrix 321. Thus, the input submatrices 301 and 303 have the following distinct elements: a1, a2, a3, a4, a5, a6, a7, a8, a9, b1, b2 and b3.

In one example, the first dot product operation and second dot product operation may be part of a (overall) convolution of the respective kernels 305 and 307 with the input matrix 321. For example, the convolution of the kernel 305 with the input matrix 321 may comprise the first dot product operation and additional dot product operations that result from sliding the kernel 305 on the input matrix 321. This may particularly be advantageous as the present method may be used in convolutions involved in neural network's operations. Thus, following the example of FIG. 3, the set of dot product operations comprise a subset of two dot product operations, the first and the second dot product operations. These two dot product operations may be performed in parallel to compute two elements of the output matrix 323 and may thus speed up the computation process comparted to a method where each element of the matrix is computed separately.

Referring back to FIG. 2, the present method may enable to perform the set of dot product operations by optimally using a crossbar array such as crossbar array 100 described with reference to FIG. 1. The set of dot product operations may be performed by computing multiple subsets of dot product operations such as the subset of dot product operations defined in FIG. 3 by the first and the second dot product operations. For example, in FIG. 3 a subset of two dot product operations are performed at the same time using the crossbar array 300. Following the example of FIG. 3, the present method may enable to compute using the crossbar array the following two results: a1*k1+a2*k2+a3*k3+a4*k4+a5*k5+a6*k6+a7*k7+a8*k8+a9*k9 which is the result of the first dot product operation and a2*k1+a3*k2+b1*k3+a5*k4+a6*k5+b2*k6+a8*k7+a9*k8+b3*k9 which is the result of the second dot product operation.

In order to compute the subset of dot product operations, an input vector that comprises distinct elements of the input submatrices may be provided. The distinct elements may be placed in the input vector following a predefined order, so that the elements of the input vector may be configured to be input at the same time to the crossbar array to the corresponding sequence of row lines of the crossbar array. For example, if the input vector comprises 5 elements, the 5 elements may be input at once to the respective 5 consecutive row lines of the crossbar array. The 5 consecutive row lines may be the first 5 row lines 102.1-5 or another sequence of the 5 consecutive row lines of the crossbar array. For example, the first element of the input vector may be input to a given row line, for example the first row line 102.1 of the crossbar array, the second element of the input vector may be input to the subsequent row line, for example the second row line 102.2 of the crossbar array and so on. Following the example of FIG. 3, the input vector 310 may comprise the distinct elements a1, a2, a3, a4, a5, a6, a7, a8, a9, b1, b2 and b3 of the input submatrices 301 and 303.

Depending on the position and order of the distinct elements in the input vector 310, the convolution matrices may be stored in step 201 accordingly in the crossbar array. For example, this may be performed by rearranging the distinct elements in the input vector multiple times, resulting in multiple rearranged input vectors. For each of the multiple rearranged input vectors the corresponding set of storage positions of the convolution matrices in the crossbar array may be determined. This may result in multiple sets of storage positions. For example, for a given rearranged input vector, the storage of the convolution matrices in the corresponding set of storage positions would enable to compute the set of dot product operations by inputting the given rearranged input vector to respective row lines of the crossbar array. Each of the set of storage position may occupy a surface of the crossbar array. In step 201, the convolution matrices may be stored in the set of storage positions that occupy the smallest surface.

The input vector of distinct elements may be input in step 203 to the crossbar array so that the subset of dot product operations may be performed using the stored convolution matrices. For example, each element of the input vector may be input to the corresponding row line of the crossbar array. The output of the columns of the crossbar array may enable to obtain the result of the subset of dot product operations.

Following the example of FIG. 3, the convolution matrices 305 and 307 may be stored in two consecutive column lines of the crossbar array 300 and the input vector comprises the distinct elements in the following order: b1, b2, b3, a2, a5, a8, a3, a6, a9, a1, a4 and a7. The output px1 of the first column would be the first result a1*k1+a2*k2+a3*k3+a4*k4+a5*k5+a6*k6+a7*k7+a8*k8+a9*k9 and the output px2 of the second column would be the second result a2*k1+a3*k2+b1*k3+a5*k4+a6*k5+b2*k6+a8*k7+a9*k8+b3*k9.

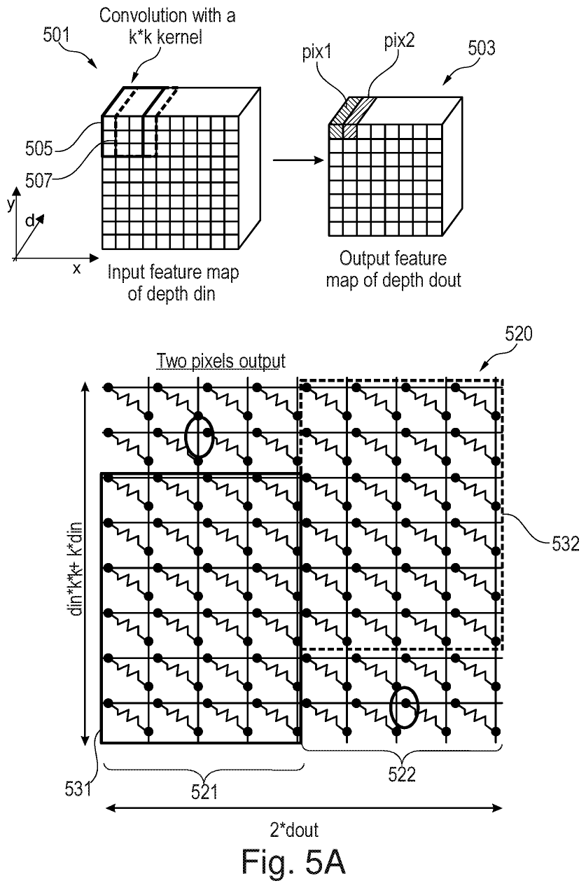

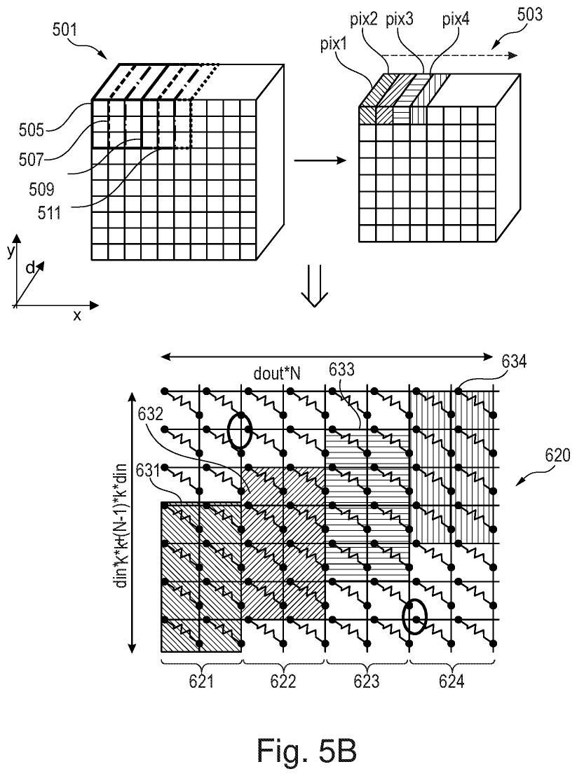

FIG. 4 is a flowchart of a method for performing at least part of an inference process of a convolutional neural network (CNN). For simplification purpose, the method of FIG. 4 is described with reference to examples of FIGS. 5A-B, but it is not limited to. The CNN may for example receive as input an input feature map 501 of depth din. The input feature map 501 may comprise din channels or layers e.g. the feature map may comprise din=3 color channels. Thus, the feature map 501 may be referred to as a multidimensional matrix. The inference process of the CNN may involve a convolution of kernels of size k*k with the input feature map 501 that results in an output feature map 503 having a depth dout. The number of kernels may for example be equal to dout. The output feature map 503 may comprise dout channels. Thus, the output feature map 503 is also a multidimensional matrix. For simplification of the description, the output feature map is shown as comprising 8×8 pixels, wherein a pixel of the pixels comprises dout elements of the output feature map 503. FIG. 5A shows two pixels pix1 and pix2. The first pixel pix1 has dout values (or elements) pix1_1, pix1_2 . . . pix1_dout in respective channels of the output feature map 503. The second pixel pix2 has dout values pix2_1, pix2_2 . . . pix2_dout in respective channels of the output feature map 503.

FIG. 5B shows four pixels pix1, pix2, pix3 and pix4. The first pixel pix1 has dout values pix1_1, pix1_2 . . . pix1_dout in respective channels of the output feature map 503. The second pixel pix2 has dout values pix2_1, pix2_2 . . . pix2_dout in respective channels of the output feature map 503. The third pixel pix3 has dout values pix3_1, pix3_2 . . . pix3_dout in respective channels of the output feature map 503. The fourth pixel pix4 has dout values pix4_1, pix4_2 . . . pix4_dout in respective channels of the output feature map 503.

For example, in order to obtain pixel values (e.g. pix1_1 and pix2_1) of a single channel of the output feature map 503 the following may be performed. A k×k kernel may be slide through a channel of the input feature map 501 in order to perform the convolution. This may result for each pixel and for each channel in a dot product operation between one kernel and one submatrix of size k*k*din. Following the example of FIGS. 5A-B, the input feature map 501 has in each channel 10×10 pixels and by sliding a 3×3 kernel on a channel, this may result in 64 dot product operations (dot product operation of a 3×3 pixels submatrix by the 3×3 kernel) for each channel of the output feature map. Each dot product operation of the input feature map 501 may involve an input submatrix 505 e.g. having a size of 3×3×din (or 3×3 pixels). For example, to obtain the pixel value pix1_1 of the first channel of the output feature map 503, one dot product operation may be performed on the respective input submatrix 505. For example, this dot product operation may be performed using the same or different 3×3 kernels for each channel of the submatrix 505. In order to obtain a single channel of the output feature map 503, 64 dot product operations are to be performed. Thus, dout*64 dot product operations are the set of dot product operations that are involved in the matrix convolution on the input feature map 501 in order to obtain the output feature map 503.

FIG. 5A illustrates one mapping method where dout*2 dot product operations may be computed in one timestep (e.g. one clock cycle) by the crossbar array. FIG. 5B illustrates one mapping of the convolutional matrices on the crossbar array such that dout*4 dot product operations may be computed in one timestep. The dout*2 dot product operations of FIG. 5A may involve dout*din*2 kernels in order to obtain the two pixels pix1 and pix2 of the output matrix. The dout*4 dot product operations of FIG. 5B may involve dout*4 kernels in order to obtain the pixels pix1, pix2, pix3 and pix4. Thus, the difference between FIG. 5A and FIG. 5B is that the subset of dot product operations to be performed on a single crossbar array is different. In FIG. 5A, two pixels pix1 and pix2 may be computed by the crossbar array 520, while in FIG. 5B, four pixels pix1, pix2, pix3 and pix4 may be computed by the crossbar array 620.

In step 401, it may be determined which subset of dot product operations, of the overall set of dot product operations, is to be performed together or in parallel using a single crossbar array. For example, in FIG. 5A, the set of dout*2 dot product operations involving the input matrices 505 and 507 may be determined or selected. In FIG. 5B, the set of dout*4 dot product operations involving the input matrices 505, 507, 509 and 511 may be determined or selected.

In step 403, the distinct elements of the input submatrices involved in the determined subset of dot product operations may be identified. In the example of FIG. 5A, the number of distinct elements in the input submatrices of the subset of dout*2 dot product operations may be equal to din*k*k+k*din, but in general the number of distinct elements in the input submatrices of the feature map 501 as shown in FIGS. 5A-B may be defined as

din*k*k+(N−1)*k*din Equation 3

where N is the number of pixels to be computed e.g. in FIG. 5A, N=2 and in FIG. 5B, N=4.

In step 405, all the kernels required for performing the determined subset of dot product operations may be stored in the crossbar array.

For example, FIG. 5A shows a crossbar array 520 having a number of row lines that correspond to the number of the identified distinct elements din*k*k+k*din and the number of columns that correspond to the number of channels of the pixels being computed. For example, in FIG. 5A, the number of column lines may be 2*dout. Each column of the crossbar array may store k*k*din kernel elements (e.g. if din=3, 3 kernels may be stored in each column). The values of the first pixel pix1 for all the dₒᵤₜ channels may be obtained by the columns 521 (e.g. the first column of columns 521 may provide value pix1_1, the second column of columns 521 may provide the value pix1_2 etc.) and the values of the second pixel pix2 for all the clout channels may be obtained by the columns 522 (e.g. first column of columns 522 may provide value pix2_1, second column of columns 522 may provide the value pix2_2 etc.). The area occupied by the kernels of FIG. 5A is defined by rectangles 531 and 532 and the remaining elements of the crossbar array may be set to zero as in indicated in FIG. 5A. The area of the crossbar array shown in FIGS. 5A-B is for illustration purpose only. For example, the size of each of the rectangles 531, 532 and 631-634 is defined by the values of the size k of the kernel, din and dout.

For example, FIG. 5B shows a crossbar array 620 having a number of row lines that correspond to the number of the identified distinct elements din*k*k+3*k*din and the number of columns that correspond to the number of channels of the pixels being computed. For example, in FIG. 5B, the number of column lines may be 4*dout. As indicated in FIG. 5B, the values of the first pixel pix1 may be obtained by the columns 621, the values of the second pixel pix2 may be obtained by the columns 622, the values of the third pixel pix3 may be obtained by the columns 623 and the values of the fourth pixel pix4 may be obtained by the columns 624. The area occupied by the kernels of FIG. 5B is defined by rectangles 631, 632, 633 and 634 and the remaining elements of the crossbar array may be set to zero as in indicated in FIG. 5B.

Thus, as shown in FIGS. 5A and 5B (and also FIG. 3) the kernels are stored on the crossbar array in a surface-efficient manner so that they occupy an optimal surface area of the crossbar array while still enabling to perform the set of dot product operations.

In step 407, the input vector of distinct elements may be input to the crossbar array 520 in order to collect the result of the computation of the determined subset of dot product operations from the crossbar array. The input vector may be input at the same time to the crossbar array so that the crossbar array can perform all the subset of dot product operations e.g. in one clock cycle.

In the example of FIG. 5A, each column may output a pixel value of a single channel of the output feature map 503 e.g. the value of pix1_1 may be the output of the first column of the columns 521 of the crossbar array 520. In the example of FIG. 5B, each column may output a pixel value of a single channel of the output feature map 503 e.g. the value of pix2_1 may be the output of the first column of the columns 622 of the crossbar array 620. The pixel values which are the output by the crossbar array may be read to provide elements of the output matrix.

The method of FIG. 4 may be repeated for further subsets of the set of dot product operations. For example, if the determined subset of dot product operations in the first execution comprises dout*2 dot product operations, the method may be repeated for another dout*2 dot product operations that would for example cover the input matrices 509 and 511 of FIG. 5B. In a given iteration of the present method, the previously stored values of the kernels in the crossbar array may be deleted (or overwritten) such that new values may be stored in the crossbar array.

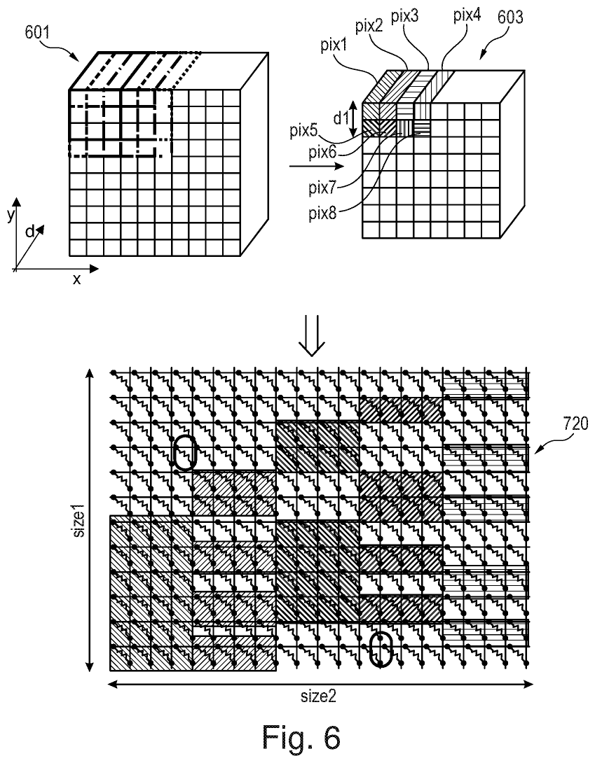

FIG. 6 illustrates a method for selecting the subset of dot product operations e.g. of FIG. 2. As with FIGS. 5A and 5B, FIG. 6 shows an input feature map 601 and an output feature map 603. The output feature map 603 comprises pixels that can be processed in accordance with the present subject matter following one horizontal direction and following a vertical direction. The number of pixels to be processed by a single crossbar array may be determined by fixing the vertical direction to a fixed number of pixels and choosing a number of pixels along the other direction such that they can be performed in parallel using a single crossbar array.

For example, by fixing the size d1 (in the vertical direction) to two pixels pix1 and pix5, other pixels on the horizontal direction may be chosen or selected. For example, if it is decided to compute four pixels, the computation of pix2 and pix6 (following the horizontal direction) may be added to the computation of pix1 and pix5. For example, if it is decided to compute 8 pixels (as shown in FIG. 6) pix2, pix6, pix3, pix7, pix4 and pix8 (following the horizontal direction) may be added to pix1 and pix5 in order to compute their values.

The total number of pixels to be computed determines the subset of dot product operations to be performed by the crossbar array. For example, by fixing d1 (i.e. fix one direction) the pixels along the other direction may be computed in parallel. In the example, of FIG. 6, dout*8 dot product operations may be performed. The kernels of the dout*8 dot product operations are stored in the crossbar array 720. As shown in FIG. 6, although some kernels do not share elements of the input vector, the overall area occupied by the kernels on the crossbar area may still be an optimal area. As with FIGS. 5A-B, FIG. 6 shows the area occupied by the convolution matrices as rectangles with different filling format, and remaining elements of the crossbar array which are not covered by that areas are set to zero.

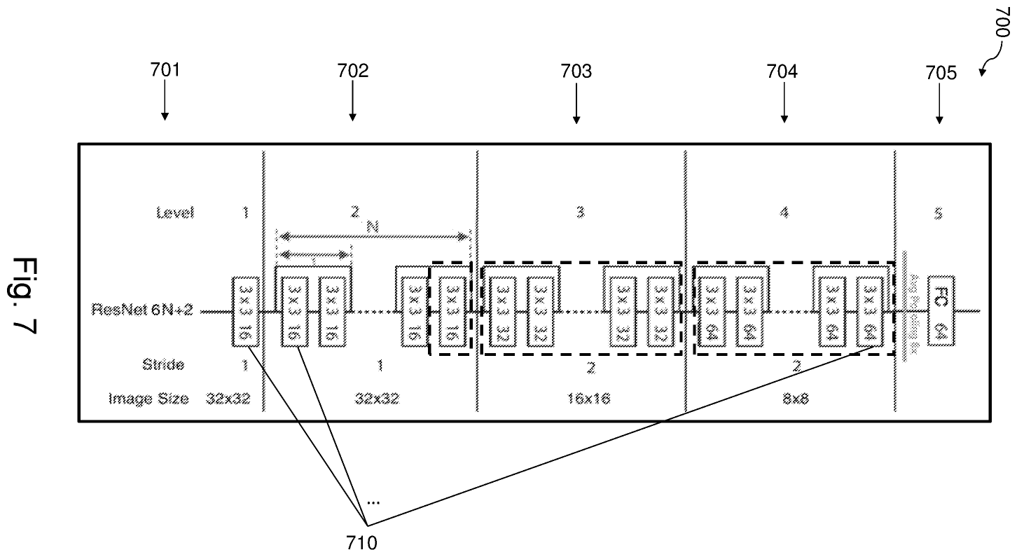

FIG. 7 illustrates a graph representation of one ResNet 700 architecture. FIG. 7 shows that the ResNet has five different levels 701-705. Each level of the levels 701-705 may involve multidimensional matrices of different sizes. For example, as shown in FIG. 7, the output matrices of level 1 701 and level 2 702 have 16 channels and involve kernels of size 3×3. The crossbar array associated with each of the layers 710 may output multiple pixels of the output matrix. For example, the crossbar array of layer 710 of level 2 may output at least two pixels, each pixel having 16 values or elements of the output matrix. This means that when the interconnect, illustrated as a line linking two consecutive layers 710, sends the data in one timestep, its bandwidth requirement may be a multiple of 16. FIG. 7 shows that the maximum bandwidth is the one used for level 4, namely a multiple of 64.

The interconnects between the crossbar arrays of the layers 710 of the ResNet may be designed based on the maximum bandwidth although some interconnects may need less than that maximum bandwidth. As a result a crossbar array of level 2 702 can be used to calculate 4 (=64/16) times as many pixels and a crossbar array of level 3 703 can calculate 2 (=64/32) times as many pixels. This way the maximum bandwidth 64 may always be used.

In one example, a CNN where each layer is associated with a crossbar array may be provided. The training or inference of the CNN may involve layer operations, such as, for example, for producing output feature maps. The crossbar arrays of the CNN may be configured to compute respective pixels of the output feature maps using the present method so that the pixels can be produced in parallel by the respective crossbar array and in a number of pixels such that the bandwidth is constant through the whole CNN network.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

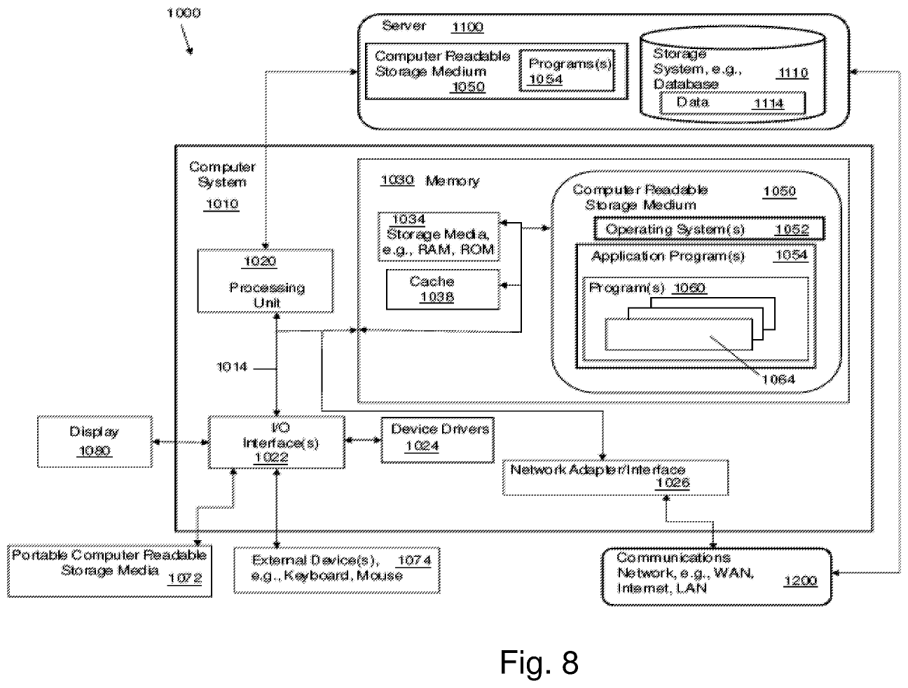

Referring to FIG. 8, a system 1000 includes a computer system or computer 1010 shown in the form of a generic computing device. The method described herein, for example, may be embodied in a program(s) 1060 (FIG. 8) embodied on a computer readable storage device, for example, generally referred to as memory 1030 and more specifically, computer readable storage medium 1050 as shown in FIG. 8. For example, memory 1030 can include storage media 1034 such as RAM (Random Access Memory) or ROM (Read Only Memory), and cache memory 1038. The program 1060 is executable by the processing unit or processor 1020 of the computer system 1010 (to execute program steps, code, or program code). Additional data storage may also be embodied as a database 1110 which can include data 1114. The computer system 1010 and the program 1060 shown in FIG. 8 are generic representations of a computer and program that may be local to a user, or provided as a remote service (for example, as a cloud based service), and may be provided in further examples, using a website accessible using the communications network 1200 (e.g., interacting with a network, the Internet, or cloud services). It is understood that the computer system 1010 also generically represents herein a computer device or a computer included in a device, such as a laptop or desktop computer, etc., or one or more servers, alone or as part of a datacenter. The computer system can include a network adapter/interface 1026, and an input/output (I/0) interface(s) 1022. The I/O interface 1022 allows for input and output of data with an external device 1074 that may be connected to the computer system. The network adapter/interface 1026 may provide communications between the computer system a network generically shown as the communications network 1200.

The computer 1010 may be described in the general context of computer system-executable instructions, such as program modules, being executed by a computer system. Generally, program modules may include routines, programs, objects, components, logic, data structures, and so on that perform particular tasks or implement particular abstract data types. The method steps and system components and techniques may be embodied in modules of the program 1060 for performing the tasks of each of the steps of the method and system. The modules are generically represented in FIG. 8 as program modules 1064. The program 1060 and program modules 1064 can execute specific steps, routines, sub-routines, instructions or code, of the program.

The method of the present disclosure can be run locally on a device such as a mobile device, or can be run a service, for instance, on the server 1100 which may be remote and can be accessed using the communications network 1200. The program or executable instructions may also be offered as a service by a provider. The computer 1010 may be practiced in a distributed cloud computing environment where tasks are performed by remote processing devices that are linked through a communications network 1200. In a distributed cloud computing environment, program modules may be located in both local and remote computer system storage media including memory storage devices.

More specifically, as shown in FIG. 8, the system 1000 includes the computer system 1010 shown in the form of a general-purpose computing device with illustrative periphery devices. The components of the computer system 1010 may include, but are not limited to, one or more processors or processing units 1020, a system memory 1030, and a bus 1014 that couples various system components including system memory 1030 to processor 1020.

The bus 1014 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

The computer 1010 can include a variety of computer readable media. Such media may be any available media that is accessible by the computer 1010 (e.g., computer system, or server), and can include both volatile and non-volatile media, as well as, removable and non-removable media. Computer memory 1030 can include additional computer readable media 1034 in the form of volatile memory, such as random access memory (RAM), and/or cache memory 1038. The computer 1010 may further include other removable/non-removable, volatile/non-volatile computer storage media, in one example, portable computer readable storage media 1072. In one embodiment, the computer readable storage medium 1050 can be provided for reading from and writing to a non-removable, non-volatile magnetic media. The computer readable storage medium 1050 can be embodied, for example, as a hard drive. Additional memory and data storage can be provided, for example, as the storage system 1110 (e.g., a database) for storing data 1114 and communicating with the processing unit 1020. The database can be stored on or be part of a server 1100. Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1014 by one or more data media interfaces. As will be further depicted and described below, memory 1030 may include at least one program product which can include one or more program modules that are configured to carry out the functions of embodiments of the present invention.

The method of the present disclosure, for example, may be embodied in one or more computer programs, generically referred to as a program(s) 1060 and can be stored in memory 1030 in the computer readable storage medium 1050. The program modules 1064 can generally carry out functions and/or methodologies of embodiments of the invention as described herein. The one or more programs 1060 are stored in memory 1030 and are executable by the processing unit 1020. By way of example, the memory 1030 may store an operating system 1052, one or more application programs 1054, other program modules, and program data on the computer readable storage medium 1050. It is understood that the program 1060, and the operating system 1052 and the application program(s) 1054 stored on the computer readable storage medium 1050 are similarly executable by the processing unit 1020.

The computer 1010 may also communicate with one or more external devices 1074 such as a keyboard, a pointing device, a display 1080, etc.; one or more devices that enable a user to interact with the computer 1010; and/or any devices (e.g., network card, modem, etc.) that enables the computer 1010 to communicate with one or more other computing devices. Such communication can occur via the Input/Output (I/O) interfaces 1022. Still yet, the computer 1010 can communicate with one or more networks 1200 such as a local area network (LAN), a general wide area network (WAN), and/or a public network (e.g., the Internet) via network adapter/interface 1026. As depicted, network adapter 1026 communicates with the other components of the computer 1010 via bus 1014. It should be understood that although not shown, other hardware and/or software components could be used in conjunction with the computer 1010. Examples, include, but are not limited to: microcode, device drivers 1024, redundant processing units, external disk drive arrays, RAID systems, tape drives, and data archival storage systems, etc.

It is understood that a computer or a program running on the computer 1010 may communicate with a server, embodied as the server 1100, via one or more communications networks, embodied as the communications network 1200. The communications network 1200 may include transmission media and network links which include, for example, wireless, wired, or optical fiber, and routers, firewalls, switches, and gateway computers. The communications network may include connections, such as wire, wireless communication links, or fiber optic cables. A communications network may represent a worldwide collection of networks and gateways, such as the Internet, that use various protocols to communicate with one another, such as Lightweight Directory Access Protocol (LDAP), Transport Control Protocol/Internet Protocol (TCP/IP), Hypertext Transport Protocol (HTTP), Wireless Application Protocol (WAP), etc. A network may also include a number of different types of networks, such as, for example, an intranet, a local area network (LAN), or a wide area network (WAN).

In one example, a computer can use a network which may access a website on the Web (World Wide Web) using the Internet. In one embodiment, a computer 1010, including a mobile device, can use a communications system or network 1200 which can include the Internet, or a public switched telephone network (PSTN) for example, a cellular network. The PSTN may include telephone lines, fiber optic cables, microwave transmission links, cellular networks, and communications satellites. The Internet may facilitate numerous searching and texting techniques, for example, using a cell phone or laptop computer to send queries to search engines via text messages (SMS), Multimedia Messaging Service (MMS) (related to SMS), email, or a web browser. The search engine can retrieve search results, that is, links to websites, documents, or other downloadable data that correspond to the query, and similarly, provide the search results to the user via the device as, for example, a web page of search results.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

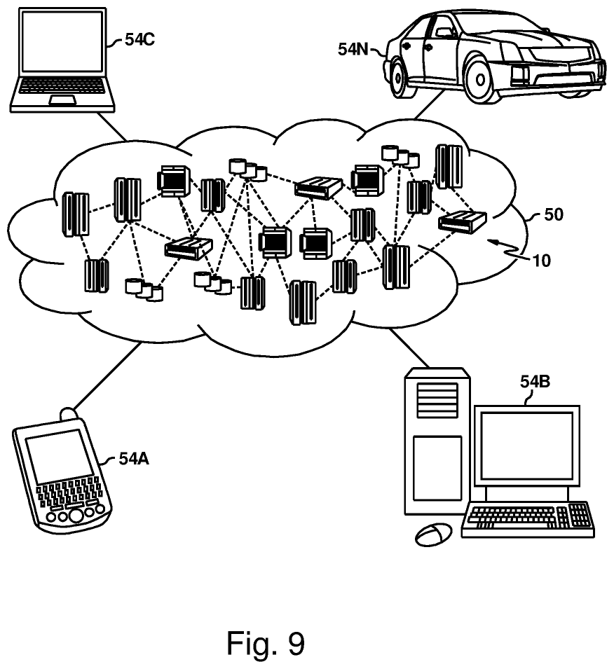

Referring now to FIG. 9, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 9 are intended to be illustrative only and that computing nodes 10 and cloud computing environment 50 can communicate with any type of computerized device over any type of network and/or network addressable connection (e.g., using a web browser).

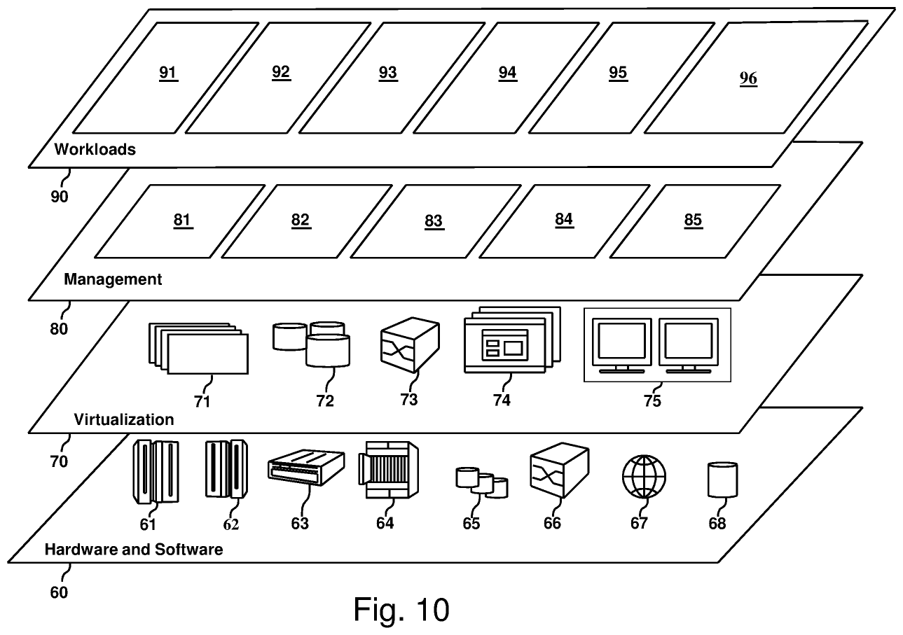

Referring now to FIG. 10, a set of functional abstraction layers provided by cloud computing environment 50 (FIG. 9) is shown. It should be understood in advance that the components, layers, and functions shown in FIG. 10 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and data classification 96.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A method for performing a matrix convolution on a multidimensional input matrix for obtaining a multidimensional output matrix, the matrix convolution involving a set of dot product operations for obtaining all elements of the output matrix, each dot product operation of the set of dot product operations involving an input submatrix of the input matrix and at least one convolution matrix, the method comprising:
providing a memristive crossbar array configured to perform a vector matrix multiplication;
computing a subset of the set of dot product operations by storing the convolution matrices of the subset of dot product operations in the crossbar array; and
inputting to the crossbar array an input vector comprising all distinct elements of the input submatrices of the subset of dot product operations.

2. The method of claim 1, wherein computing the subset of the set of dot product operations further comprises:
selecting the subset of dot product operations such that the computation of the subset of dot product operations results in elements along two dimensions of the output matrix and such that each selected subset of dot product operations involves a different input vector.

3. The method of claim 1, wherein computing the subset of the set of dot product operations further comprises:
selecting the subset of dot product operations such that the computation of the subset of dot product operations results in elements along three dimensions of the output matrix and such that each selected subset of dot product operations involves a different input vector.

4. The method of claim 1, wherein a training or inference of a convolutional neural network involves at each layer of the convolutional neural network a layer operation that can be computed by the memristive crossbar array, wherein the matrix convolution is the layer operation of a given layer of the convolutional neural network.

5. The method of claim 4, wherein providing the memristive crossbar array configured to perform the vector matrix multiplication further comprises:
providing further memristive crossbar arrays such that each further layer of the convolutional neural network is associated with the memristive crossbar array;
interconnecting the memristive crossbar arrays for execution in a pipelined fashion; and
performing the computation step for each further layer of the convolutional neural network using a respective subset of dot product operations and the memristive crossbar array associated with the further layer of the convolutional neural network.

6. The method of claim 5, wherein the subset of dot product operations computed by each memristive crossbar array is selected such that a bandwidth requirement for each interconnection between the interconnected memristive crossbar arrays is identical.

7. The method of claim 1, wherein the memristive crossbar array comprises row lines and column lines intersecting the row lines, and resistive memory elements coupled between the row lines and the column lines at junctions formed by the row and column lines, a resistive memory element of the resistive memory elements representing a value an element of a matrix.

8. The method of claim 7, wherein storing the convolution matrices comprises:
for each dot product operation of the subset of dot product operations, storing all elements of convolution matrices involved in the dot product operation in resistive memory elements of a respective single column line of the crossbar array.

9. The method of claim 7, wherein storing of the convolution matrices comprises:
storing all the elements of convolution matrices involved in each dot product operation of the subset in a respective column line, the column lines outputting different outputs being consecutive column lines of the crossbar array.

10. The method of claim 1, wherein storing of the convolution matrices comprises:
identifying a group of convolution matrices of the convolution matrices that are to be multiplied by the same input submatrix, storing all elements of each convolution matrix of the group in a column line of the crossbar array; and
repeating the identifying step and storing step for zero or more further groups of convolution matrices.

11. The method of claim 1, wherein the input and the output matrices comprise pixels of images or activation values from a layer of a convolutional neural network and the convolution matrices being kernels.

12. A memristive crossbar array for performing a matrix convolution on a multidimensional input matrix for obtaining a multidimensional output matrix, the matrix convolution involving a set of dot product operations for obtaining all elements of the output matrix, each dot product operation of the set of dot product operations involving an input submatrix of the input matrix and at least one convolution matrix, the crossbar array being configured for storing the convolution matrices in the crossbar array such that one input vector comprising all distinct elements of the input submatrices can be input to the crossbar array in order to perform a subset of dot product operations of the set of dot product operations.

13. A computer program product for performing a matrix convolution on a multidimensional input matrix for obtaining a multidimensional output matrix, the matrix convolution involving a set of dot product operations for obtaining all elements of the output matrix, each dot product operation of the set of dot product operations involving an input submatrix of the input matrix and at least one convolution matrix, the computer program product comprising:
a computer-readable storage medium having program code embodied therewith, the program code executable by at least one hardware processor to:
provide a memristive crossbar array configured to perform a vector matrix multiplication;
compute a subset of the set of dot product operations by storing the convolution matrices of the subset of dot product operations in the crossbar array; and
inputting to the crossbar array one input vector comprising all distinct elements of the input submatrices of the subset.

14. The computer program product of claim 13, wherein computing the subset of the set of dot product operations further comprises:
selecting the subset of dot product operations such that the computation of the subset of dot product operations results in elements along two dimensions of the output matrix and such that each selected subset of dot product operations involves a different input vector.

15. The computer program product of claim 13, wherein computing the subset of the set of dot product operations further comprises:
selecting the subset of dot product operations such that the computation of the subset of dot product operations results in elements along three dimensions of the output matrix and such that each selected subset of dot product operations involves a different input vector.

16. The computer program product of claim 13, wherein a training or inference of a convolutional neural network involves at each layer of the convolutional neural network a layer operation that can be computed by the memristive crossbar array, wherein the matrix convolution is the layer operation of a given layer of the convolutional neural network.

17. The computer program product of claim 16, wherein providing the memristive crossbar array configured to perform the vector matrix multiplication further comprises:
providing further memristive crossbar arrays such that each further layer of the convolutional neural network is associated with the memristive crossbar array;
interconnecting the memristive crossbar arrays for execution in a pipelined fashion; and
performing the computation step for each further layer of the convolutional neural network using a respective subset of dot product operations and the memristive crossbar array associated with the further layer of the convolutional neural network.

18. The computer program product of claim 17, wherein the subset of dot product operations computed by each memristive crossbar array is selected such that a bandwidth requirement for each interconnection between the interconnected memristive crossbar arrays is identical.

19. The computer program product of claim 13, wherein the memristive crossbar array comprises row lines and column lines intersecting the row lines, and resistive memory elements coupled between the row lines and the column lines at junctions formed by the row and column lines, a resistive memory element of the resistive memory elements representing a value an element of a matrix.

20. The computer program product of claim 13, wherein storing of the convolution matrices comprises:
identifying a group of convolution matrices of the convolution matrices that are to be multiplied by the same input submatrix, storing all elements of each convolution matrix of the group in a column line of the crossbar array; and
repeating the identifying step and storing step for zero or more further groups of convolution matrices.
